(19) United States
(12) Patent Application Publication
(10) Pub. No.: US 2025/0006878 A1
(43) Pub. Date: Jan. 2, 2025

(54) DISPLAY SUBSTRATE AND DISPLAY DEVICE

(71) Applicants: Hefei BOE Ruisheng Technology Co., Ltd., Hefei, Anhui (CN); BOE Technology Group Co., Ltd., Beijing (CN)

(72) Inventors: Jie WANG, Beijing (CN); Xintao WU, Beijing (CN); Jiawei XU, Beijing (CN); Zouming XU, Beijing (CN)

(21) Appl. No.: 18/277,371

(22) PCT Filed: Nov. 29, 2022
(86) PCT No.: PCT/CN2022/134926

§ 371 Date: Aug. 15, 2023

(51) Int. Cl. H01L 33/62; H01L 25/16

(52) U.S. Cl. CPC H01L 33/62; H01L 25/167

(57) ABSTRACT

Provided is a display substrate. The display substrate includes a base substrate, a plurality of conductive pads, a first organic insulating layer, and a first inorganic insulating layer. The first organic insulating layer is disposed on the base substrate provided with the conductive pads and provided with a first opening corresponding to at least one conductive pad, and the first inorganic insulating layer is disposed on a side of the first organic insulating layer facing away from the base substrate and provided with a plurality of second openings corresponding to the plurality of conductive pads. An orthographic projection of at least one conductive pad on the base substrate is within an orthographic projection of the corresponding first opening on the base substrate, and an orthographic projection of the second opening on the base substrate is within the orthographic projection of the corresponding conductive pad on the base substrate.

### CROSS-REFERENCE TO RELATED APPLICATION

This application is a U.S. national stage of international application No. PCT/CN2022/134926, filed on Nov. 29, 2022, the disclosure of which is incorporated herein by reference in its entirety.

### TECHNICAL FIELD

The present disclosure relates to the field of display technologies, and in particular, relates to a display substrate and a display device.

### BACKGROUND

Currently, compared with traditional LEDs, micro light-emitting diodes (Micro LEDs) and mini light-emitting diode (Mini LEDs) has a smaller volume, and are widely used in display devices.

### SUMMARY

Embodiments of the present disclosure provide a display substrate and a display device. The technical solutions are as follows.

According to some embodiments of the present disclosure, a display substrate is provided. The display substrate includes:
a base substrate;
a plurality of conductive pads disposed on the base substrate;
a first organic insulating layer disposed on the base substrate provided with the conductive pads, wherein the first organic insulating layer is provided with a plurality of first openings, the first opening corresponds to at least one conductive pad, and an orthographic projection of the at least one conductive pad on the base substrate is within an orthographic projection of the corresponding first opening on the base substrate; and
a first inorganic insulating layer disposed on a side of the first organic insulating layer facing away from the base substrate, wherein the first inorganic insulating layer is provided with a plurality of second openings, the second opening corresponds to the conductive pad, and an orthographic projection of the second opening on the base substrate is within an orthographic projection of the corresponding conductive pad on the base substrate.

In some embodiments, the display substrate further includes: a conductive anti-oxidation layer, wherein the conductive anti-oxidation layer is disposed on the base substrate provided with the first inorganic insulating layer, an orthographic projection of the conductive anti-oxidation layer on the base substrate is within an orthographic projection of the second opening on the base substrate, and the conductive anti-oxidation layer covers a surface, away from the base substrate, of a pad region of the conductive pad, the pad region being a region of the conductive pad which is exposed from the second opening.

In some embodiments, a minimum distance between two adjacent conductive pads is greater than or equal to a first preset value, and the first opening corresponds to one conductive pad.

In some embodiments, a minimum distance between two adjacent conductive pads is less than a first preset value, and the first opening corresponds to a plurality of conductive pads.

In some embodiments, the first preset value ranges from 30 μm to 60 μm.

In some embodiments, the plurality of conductive pads include a plurality of first conductive pads and a plurality of second conductive pads; wherein
every two first conductive pads constitute one first conductive pad group, and one first conductive pad group is configured to be connected to one light-emitting device;
every N second conductive pads constitute one second conductive pad group, and one second conductive pad group is configured to be connected to one driver chip; and
the first openings include a first sub-opening and a second sub-opening, wherein the first sub-opening corresponds to one first conductive pad group, and the second sub-opening corresponds to one second conductive pad group.

In some embodiments, the plurality of conductive pads include a plurality of first conductive pads and a plurality of second conductive pads; wherein
every two first conductive pads constitute one first conductive pad group, and one first conductive pad group is configured to be connected to one light-emitting device;
every N second conductive pads constitute one second conductive pad group, and each second conductive pad group is configured to be connected to one driver chip; and
the first openings include a first sub-opening and a second sub-opening, wherein the first sub-opening corresponds to at least three adjacent first conductive pad groups, and the second sub-opening corresponds to one second conductive pad group.

In some embodiments, a distance between the first sub-opening and the second sub-opening adjacent to each other ranges from 20 μm to 100 μm.

In some embodiments, the first opening corresponds to at least one second opening, and an orthographic projection of the at least one second opening on the base substrate is within an orthographic projection of the corresponding first opening on the base substrate; and
a minimum distance between an edge of the orthographic projection of the first opening on the substrate and an edge of the orthographic projection of the at least one second opening on the base substrate ranges from 20 μm to 80 μm.

In some embodiments, the display substrate is rectangular and the display substrate has two opposite first edges and two opposite second edges;
the display substrate further includes connection terminals and side wires which are located at the second edges, the connection terminal and the side wire being electrically connected to each other;
the plurality of first openings include a target first opening, wherein the target first opening is adjacent to the first edge, and an edge of the target first opening coincides with an edge, which is located at the first edge, of the first organic insulating layer.

In some embodiments, the first organic insulating layer is further provided with a third opening; wherein the third opening is adjacent to the second edge and corresponds to at least one conductive pad, and an edge of an orthographic projection of the third opening on the base substrate is at least partially outside an orthographic projection of at least one corresponding conductive pad on the base substrate; and
there is a second preset distance between an edge of the third opening and an edge, which is located at the second edge, of the first organic insulating layer.

In some embodiments, the second preset distance ranges from 20 μm to 50 μm.

In some embodiments, the display substrate is further provided with an alignment mark, and the first organic insulating layer is further provided with a fourth opening adjacent to the alignment mark; wherein
the fourth opening corresponds to one conductive pad, and an orthographic projection of the fourth opening on the base substrate is within an orthographic projection of the corresponding conductive pad on the base substrate.

In some embodiments, the display substrate further includes: a first wiring pattern and a second insulating layer which are disposed between the plurality of conductive pads and the base substrate, wherein the first wiring pattern and the second insulating layer are stacked in a direction going away from the base substrate, and the second insulating layer is provided with a via hole, an orthographic projection of the via hole on the base substrate being at least partially overlapped with an orthographic projection of the first wiring pattern on the base substrate;
the display substrate further includes a second wiring pattern which is disposed in a same layer as the plurality of conductive pads and electrically connected to the plurality of conductive pads, wherein the second wiring pattern is electrically connected to the first wiring pattern through the via hole;
wherein an edge of an orthographic projection of the first opening on the substrate is staggered with an edge of an orthographic projection of the via hole on the base substrate.

According to some embodiments of the embodiments of the present disclosure, a display device is provided. The display device includes the display substrate as described in the above aspect.

### BRIEF DESCRIPTION OF DRAWINGS

To describe the technical solutions in the embodiments of the present disclosure more clearly, the accompanying drawings required for describing the embodiments are described below. The accompanying drawings in the following description show merely some embodiments of the present disclosure, and those of ordinary skill in the art may still derive other drawings from these accompanying drawings without creative effort.

FIG. 1 is a schematic structural diagram of a display substrate;

FIG. 2 is a schematic diagram of coverage of a first organic insulating layer in the display substrate as shown in FIG. 1;

FIG. 3 is a cross-sectional structural diagram of the display substrate as shown in FIG. 1 along a position A1-A2;

FIG. 4 is a schematic structural diagram of a display substrate according to some embodiments of the present disclosure;

FIG. 5 is a schematic diagram showing a position relationship between a first organic insulating layer and a plurality of conductive pads in the display substrate as shown in FIG. 4;

FIG. 6 is a cross-sectional structural diagram of the display substrate as shown in FIG. 4 along a position B1-B2;

FIG. 7 is a schematic structural diagram of another display substrate according to some embodiments of the present disclosure;

FIG. 8 is a cross-sectional structural diagram of the display substrate as shown in FIG. 7 along a position C1-C2;

FIG. 9 is a schematic structural diagram of another display substrate according to some embodiments of the present disclosure;

FIG. 10 is a schematic structural diagram of another display substrate according to some embodiments of the present disclosure;

FIG. 11 shows another display substrate according to some embodiments of the present disclosure;

FIG. 12 shows another display substrate according to some embodiments of the present disclosure;

FIG. 13 shows another display substrate according to some embodiments of the present disclosure;

FIG. 14 is a cross-sectional structural diagram of the display substrate as shown in FIG. 13 along a position D1-D2; and

FIG. 15 is a flowchart of a method for manufacturing a display substrate according to some embodiments of the present disclosure.

Specific embodiments of the present disclosure have been shown in the foregoing drawings and will be described in more detail hereinafter. These drawings and text descriptions are not intended in any way to limit the scope of the concepts of the present disclosure, but rather to illustrate the concepts of the present disclosure to those skilled in the art by referring to the specific embodiments.

### DETAILED DESCRIPTION

To make the objectives, technical solutions, and advantages of the present disclosure clearer, the embodiments of the present disclosure will be further described in detail below with reference to the accompanying drawings.

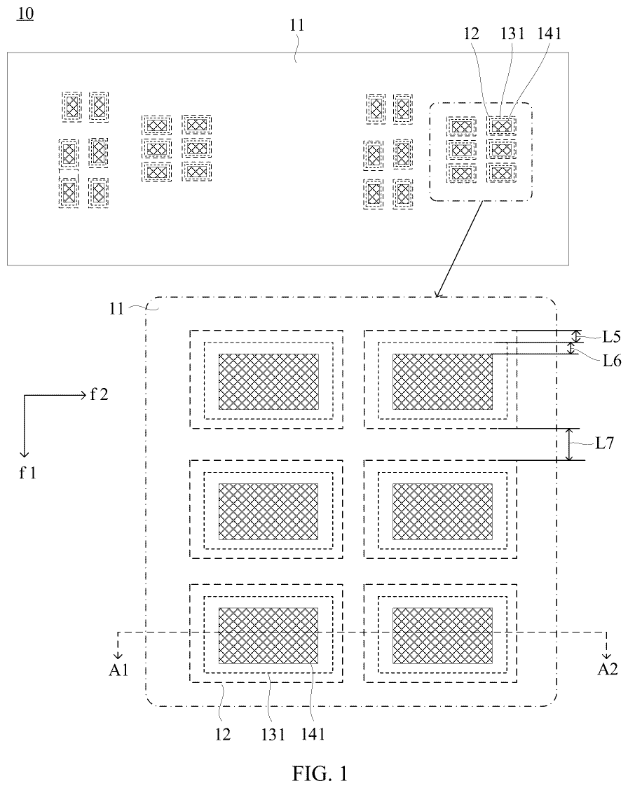

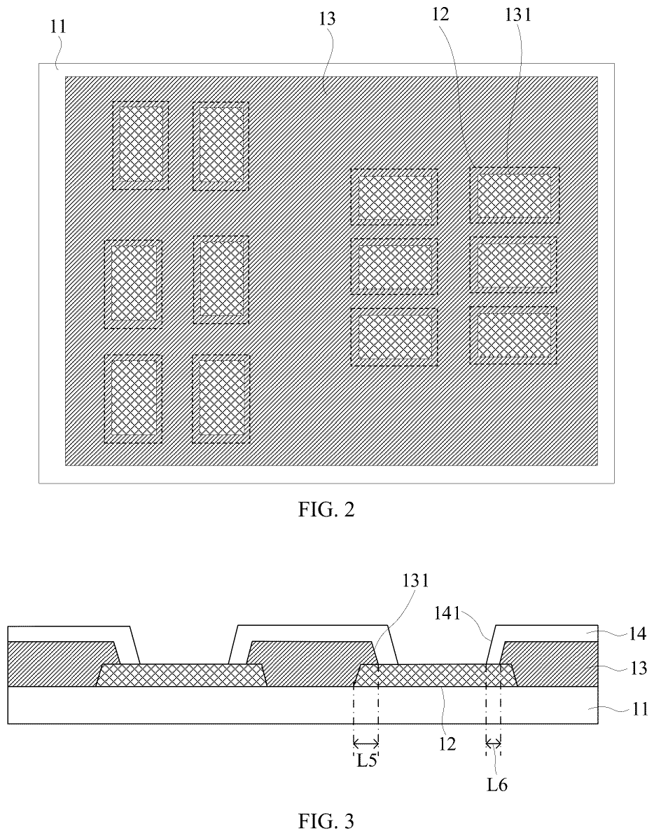

FIG. 1 is a structural diagram of a substrate 10. FIG. 2 is a schematic diagram of coverage of a first organic insulating layer 13 in the display substrate 10 as shown in FIG. 1. FIG. 3 is a cross-sectional structural diagram of the display substrate 10 as shown in FIG. 1 along a position A1-A2. Referring to FIGS. 1-3, the display substrate 10 includes a base substrate 11, a plurality of conductive pads 12, a first organic insulating layer 13 and a first inorganic insulating layer 14. The plurality of conductive pads 12, the first organic insulating layer 13 and the first inorganic insulating layer 14 are laminated on the base substrate 11 along a direction going away from the base substrate 11. The plurality of conductive pads 12 includes a plurality of first conductive pads configured to be connected to a light-emitting device and a plurality of second conductive pads configured to be connected to a driver chip.

FIG. 2 only shows a position relationship between the first organic insulating layer 13 and the plurality of conductive pads 12. As can be seen from FIG. 1 and FIG. 2, a plurality of second openings 141 are in one-to-one correspondence with the plurality of conductive pads 12, and a plurality of first openings 131 are also in one-to-one correspondence with the plurality of conductive pads 12.

It should be noted that after the first inorganic insulating layer 14 is formed on the display substrate, an electroless gold plating process may be performed subsequently. During the electroless gold plating process, the first organic insulating layer 13 exposed from the first inorganic insulating layer 14 can absorb the electroless gold plating solution in the electroless gold plating process and generate tiny bubbles in the electroless gold plating solution. These tiny bubbles cause a metal plating layer formed by depositing the electroless gold plating solution in the pad region of the conductive pad 12 to be incomplete, that is, the metal plating layer cannot cover the pad region exposed from the first inorganic insulating layer 14.

As a result, the integrity of the metal plating layer is poor, resulting in a low yield of the plurality of pads in the display substrate 10, and the light-emitting device or the driver chip cannot be well electrically connected to the display substrate 10. Thus, the yield of the display substrate 10 is low.

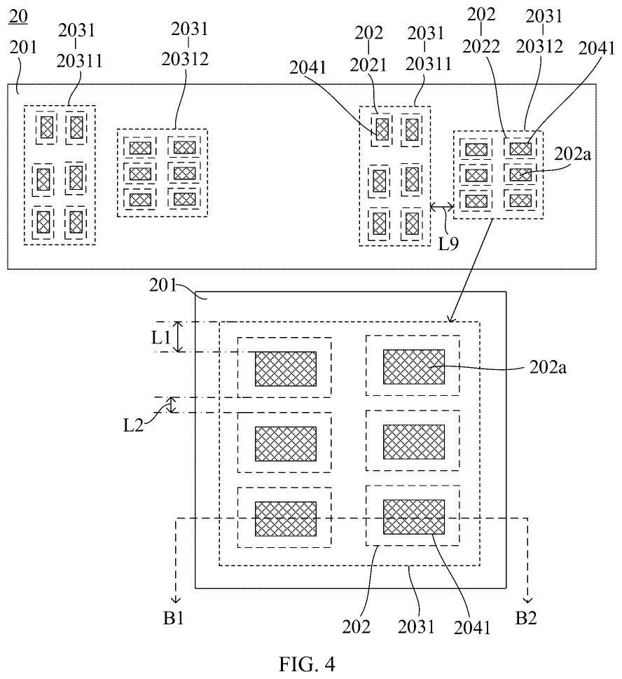

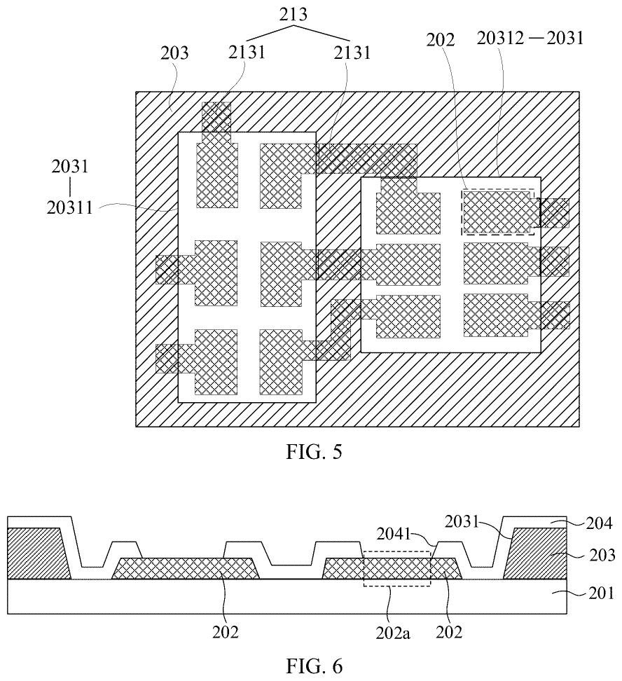

FIG. 4 is a schematic structural diagram of a display substrate 20 according to some embodiments of the present disclosure. FIG. 5 is a schematic diagram showing a position relationship between a first organic insulating layer 203 and a plurality of conductive pads 202 in the display substrate 20 as shown in FIG. 4. FIG. 6 is a cross-sectional structural diagram of the display substrate 20 as shown in FIG. 4 along a position B1-B2. The display substrate 20 includes a base substrate 201, a plurality of conductive pads 202, a first organic insulating layer 203 and a first inorganic insulating layer 204.

The plurality of conductive pads 202 are disposed on the base substrate 201, and the first organic insulating layer 203 is disposed on the base substrate 201 provided with the conductive pads 202. The first organic insulating layer 203 is provided with a plurality of first openings 2031, and the first openings 2031 run through the first organic insulating layer 203. The first opening 2031 corresponds to at least one conductive pad 202, and the orthographic projection of the at least one conductive pad 202 on the base substrate 201 is within the orthographic projection of the corresponding first opening 2031 on the base substrate 201. As shown in FIG. 4, the orthographic projection of one or more conductive pads 202 on the base substrate 201 is within the orthographic projection of one first opening 2031 on the base substrate 201, and one first opening 2031 in the first organic insulating layer 203 exposes one or more conducting pads 202.

The first inorganic insulating layer 204 is disposed on the side of the first organic insulating layer 203 facing away from the base substrate 201. The first inorganic insulating layer 204 is provided with a plurality of second openings 2041. The second opening 2041 corresponds to the conductive pad 202, and the orthographic projection of the second opening 2041 on the base substrate 201 is within the orthographic projection of the corresponding conductive pad 202 on the base substrate 201. The plurality of second openings 2041 are in one-to-one correspondence with the plurality of conductive pads 202. One second opening 2041 in the first inorganic insulating layer 204 exposes a partial region of one conductive pad 202, and the partial region is referred to as a pad region 202a.

It should be noted that in the manufacturing process of the display substrate 20, a conductive anti-oxidation layer is formed by an electroless gold plating process on the base substrate 201 on which the first inorganic insulating layer 204 is formed, and the conductive anti-oxidation layer is a metal plating layer on the conductive pad 202. Compared with the solution in the related art where the orthographic projection of the first opening 2031 on the base substrate 201 is within the orthographic projection of the corresponding conductive pad 202 on the base substrate 201, the distance between the first opening 2031 and the second opening 2041 is increased in the embodiments of the present disclosure. Thus, the distance between the first organic insulating layer 203 and the pad region 202a of the conductive pad 202 exposed from the second opening 2041 is increased, which can improve the coverage effect of the first inorganic insulating layer 204 on the first organic insulating layer 203, and prevent the contact between the first organic insulating layer 203 exposed from the first inorganic insulating layer 204 and the electroless gold plating solution during the manufacturing process of the display substrate 20, thereby avoiding the problem of an incomplete metal plating layer in the pad region 202a of the conductive pad 202. Therefore, the yield of the plurality of pads in the display substrate 20 is improved. The pad is the pad region 202a covered with the conductive anti-oxidation layer, and the pad is configured to be bonded with a light-emitting device or a driver chip.

In summary, the embodiments of the present disclosure provide a display substrate, including a base substrate, a plurality of conductive pads, a first organic insulating layer, and a first inorganic insulating layer. The first organic insulating layer is provided with a first opening corresponding to at least one conductive pad, and the first inorganic insulating layer is provided with a second opening corresponding to the conductive pad. The orthographic projection of at least one conductive pad on the base substrate is within the orthographic projection of the corresponding first opening on the base substrate, and the orthographic projection of the second opening on the base substrate is within the orthographic projection of the corresponding conductive pad on the base substrate. Compared with the solution in the related art where the orthographic projection of the first opening on the base substrate is within the orthographic projection of the corresponding conductive pad on the base substrate, the distance between the edge of the first opening and the edge of the second opening in the embodiments of the present disclosure is larger, that is, the distance between the first organic insulating layer and the pad region of the conductive pad exposed from the second opening is increased, which can prevent the first organic insulating layer from affecting the metal plating layer in the pad region of the conductive pad exposed from the second opening. Therefore, the problem of the low yield of the display substrate in related art can be solved, and the yield of the display substrate can be improved.

In some embodiments, as shown in FIG. 5, the display substrate 20 further includes a second wiring pattern 213 which is disposed in the same layer as the plurality of conductive pads 202 and electrically connected to the plurality of conductive pads 202. The plurality of conductive pads 202 and the second wiring pattern 213 are disposed on the side of the first organic insulating layer 203 close to the base substrate 201, and the second wiring pattern 213 includes a plurality of second signal lines 2131. It is understood that the conductive pad 202 and the second signal line 2131 in direct contact with the conductive pad 202 is integrated, or the conductive pad 202 is made of the same material as the second wiring pattern 213. In some embodiments, the conductive pad 202 and the second wiring pattern 213 are integrated, or the conductive pad 202 is made of the same material as the second wiring pattern 213.

It should be noted that since the orthographic projection of the second opening (not shown in FIG. 5) on the base substrate 201 is within the orthographic projection of the conductive pad 202 on the base substrate 201, the second opening does not expose the second signal line 2131, thereby protecting the second signal line 2131 by the first inorganic insulating layer.

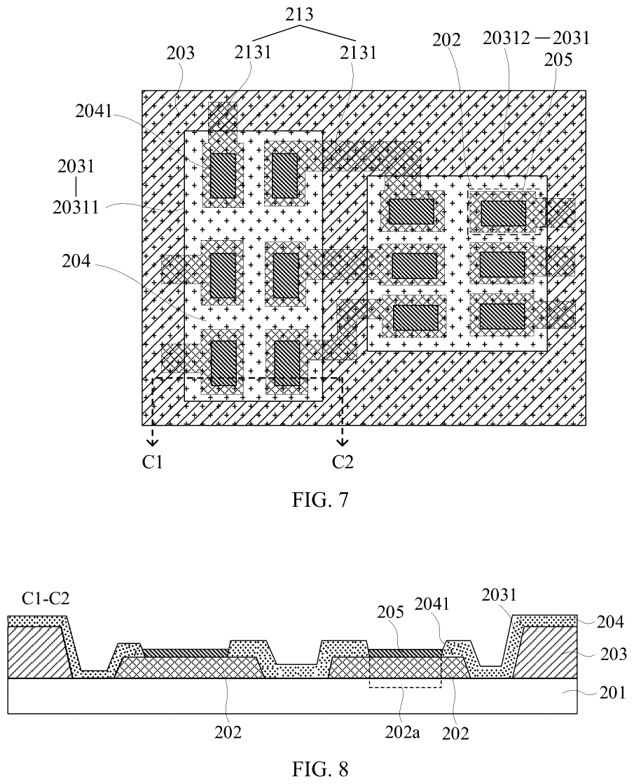

In some embodiments, FIG. 7 is a schematic structural diagram of another display substrate 20 according to some embodiments of the present disclosure, and FIG. 8 is a cross-sectional structural diagram of the display substrate 20 as shown in FIG. 7 along a position C1-C2. Referring to FIG. 7 and FIG. 8, the conductive pad 202 is exposed from the first organic insulating layer 203 through the corresponding first opening 2031. The conductive pad 202 has a top surface and a bottom surface which are opposite, and the top surface is on the side, away from the base substrate 201, of the bottom surface. The top surface of the conductive pad 202 is exposed from the first inorganic insulating layer 204 through the corresponding second opening 2041, and the region of the conductive pad 202 exposed through the second opening 2041 is the pad region 202a.

The display substrate 20 further includes a conductive anti-oxidation layer 205, which is disposed on the base substrate 201 provided with the first inorganic insulating layer 204. The orthographic projection of the conductive anti-oxidation layer 205 on the base substrate 201 is within the orthographic projection of the second opening 2041 on the base substrate 201, and the conductive anti-oxidation layer 205 covers the surface, away from the base substrate 201, of the pad region 202a of the conductive pad 202. The pad region 202a is a region of the conductive pad 202 exposed from the second opening 2041, that is, the conductive anti-oxidation layer 205 covers the region of conductive pad 202 exposed from the second opening 2041. The conductive anti-oxidation layer 205 includes a metal plating layer which is on the top surface, exposed from the second opening 2041, of the conductive pad 202. The material of the conductive anti-oxidation layer 205 includes at least one of nickel (Ni), gold (Au) and titanium (Ti), and the material of the conductive pad 202 includes at least one of copper (Cu) and molybdenum-niobium alloys (MoNb).

The conductive anti-oxidation layer 205 formed by the electroless gold plating process is of a crystal structure. The crystal structure is easier to weld than the surface of the conductive pad 202, which makes the electrical connection between the conductive pad 202 and the pin of the light-emitting device or the pin of the driver chip more stable. In addition, the material of the conductive anti-oxidation layer 205 has more stable chemical properties than the material of the conductive pad 202, and thus the conductive anti-oxidation layer 205 can protect the conductive pad 202 from oxidation.

In an exemplary embodiment, a larger display device can be assembled by splicing multiple smaller display devices, which can improve the product reliability and reduce the transportation and maintenance costs. Since there is a bonding region on the front (i.e., the surface where the display surface is located) of the display device, the display device has a wider border, and the splicing gap caused by the wider border affects the optical uniformity of the larger display device. Therefore, the wires on the display side of the display device are connected to the circuit board (e.g., a flexible circuit board) on the non-display side of the display substrate by side wires, which can reduce the border size of the smaller display device and reduce the spacing between adjacent smaller display devices.

In the related art, there are process steps to turn over or move the display substrate 10 during the manufacturing process of the display substrate 10. For example, the display substrate 10 has a front face and a back face. Process steps associated with the conductive pads 12, the first organic insulating layer 13, the first inorganic insulating layer 14 and the like are first carried out on the front face of the display substrate 10. Then, the display substrate 10 is turned over to carry out process steps related to the wires on the back face of the display substrate 10, and then the electroless gold plating process is performed on the conductive pad 12 on the display substrate 10 to form a metal plating layer on the surface of the pad region 202a of the conductive pad 12. In this way, the formed pad has good weldability and electrical properties. Because the film layer on the front surface of the display substrate 10 is in direct contact with the manufacturing equipment during the process steps related to the wires on the back surface, the manufacturing equipment is likely to scratch part of the first inorganic insulating layer 14 on the front surface, making this part of the first inorganic insulating layer 14 unable to completely cover the lower layer of first organic insulating layer 13.

It should be noted that after the first inorganic insulating layer 14 is formed on the display substrate, an electroless gold plating process is performed subsequently. The electroless gold plating process is used to form a conductive anti-oxidation layer on the base substrate 11 on which the first inorganic insulating layer 14 is formed. The conductive anti-oxidation layer is a metal plating layer in the pad region of the conductive pad 12. The electroless gold plating process is also referred to as a gold depositing process, which is a gold plating process to deposit metal onto the surface of the pad region of the conductive pad 12 by means of a chemical reaction in the solution. The solution used in the process is referred to as an electroless gold plating solution.

During the electroless gold plating process, the first organic insulating layer 13 exposed from the first inorganic insulating layer 14 can absorb the electroless gold plating solution in the electroless gold plating process, and generate tiny bubbles in the electroless gold plating solution. These tiny bubbles cause a metal plating layer formed by depositing the electroless gold plating solution in the pad region of the conductive pad 12 to be incomplete, that is, the metal plating layer cannot cover the pad region of the conductive pad 12 exposed from the first inorganic insulating layer 14.

Alternatively, due to the process fluctuation in the manufacturing process of the display substrate 10, the laminated layers cannot achieve an expected coverage effect. For example, the first inorganic insulating layer 14 does not completely cover the first organic insulating layer 13, which causes the first organic insulating layer 13 to affect the metal plating layer.

Therefore, the integrity of the metal plating layer in the related art is poor. In the embodiments of the present disclosure, the conductive anti-oxidation layer 205 is not easily affect by the first organic insulating layer 203 during the manufacturing process of the conductive anti-oxidation layer 205. Therefore, the conductive anti-oxidation layer 205 can completely cover the pad region 202a of the conductive pad 202 exposed from the second opening 2041, thereby improving the yield of display substrate 20.

In some embodiments, as shown in FIG. 4, the first opening 2031 corresponds to at least one second opening 2041, and the orthographic projection of at least one second opening 2041 on the base substrate 201 is within the orthographic projection of the corresponding first opening 2031 on the base substrate 201. The minimum distance L1 between the edge of the orthographic projection of the first opening 2031 on the base substrate 201 and the edge of the orthographic projection of at least one second opening 2041 on the base substrate 201 ranges from 20 μm to 80 μm, and further the minimum distance L1 between the edge of the orthographic projection of the first opening 2031 on the base substrate 201 and the edge of the orthographic projection of the corresponding at least one second opening 2041 on the base substrate 201 ranges from 20 μm to 80 μm. Exemplarily, the minimum distance L1 between the edge of the orthographic projection of the first opening 2031 on the base substrate 201 and the edge of the orthographic projection of the corresponding at least one second opening 2041 on the base substrate 201 is 50 μm.

Compared with the solution in the related art where the minimum distance between the edge of the first opening 2031 on the base substrate 201 and the edge of the corresponding second opening 2041 on the base substrate 201 ranges from 2 μm to 5 μm, the distance between the first opening 2031 and the second opening 2041 is larger in the embodiments of the present disclosure. That is, the distance between the first organic insulating layer 203 and the pad region 202a of the conductive pad 202 exposed from the second opening 2041 is larger, which can improve the coverage effect of the first inorganic insulating layer 204 on the first organic insulating layer 203, and prevent the contact between the first organic insulating layer 203 exposed from the first inorganic insulating layer 204 and the electroless gold plating solution during the manufacturing process of the display substrate 20, thereby avoiding the problem of an incomplete metal plating layer in the pad region 202a of the conductive pad 202. Therefore, the yield of the plurality of pads in the display substrate 20 is improved.

In the embodiments of the present disclosure, even though a region of the first inorganic insulating layer 204 is scratched in the manufacturing process of the display substrate 20, exposing a partial region of the first organic insulating layer 203, the first organic insulating layer 203 has little influence on the electroless gold plating solution in the pad region 202a of the conductive pad 202 exposed from the second opening 2041 since the distance between the edge of the first organic insulating layer 203 (i.e., the edge of the first opening 2031) and the pad region 202a of the conductive pad 202 exposed from the second opening 2041 is larger in the embodiments of the present disclosure. Further, the first organic insulating layer 203 exposed from the first inorganic insulating layer 204 is prevented from contacting the electroless gold plating solution during the manufacturing process of the display substrate 20, thereby avoiding the problem of an incomplete metal plating layer on pad region 202a of the conductive pad 202. Therefore, the yield of the plurality of pads in the display substrate 20 is improved.

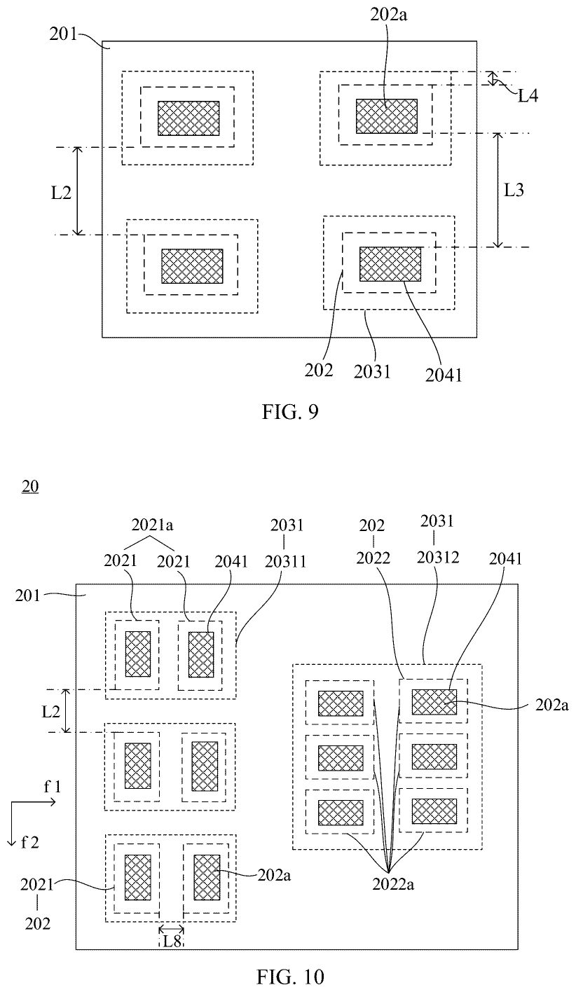

In some embodiments, FIG. 9 is a schematic structural diagram of another display substrate 20 according to some embodiments of the present disclosure. Referring to FIG. 9, the minimum distance L2 between two adjacent conductive pads 202 is greater than or equal to a first preset value, and the first opening 2031 corresponds to one conductive pad 202. That is, in the case that the plurality of conductive pads 202 are arranged sparsely on the display substrate 20, the first organic insulating layer 203 can expose one conductive pad 202 through one first opening 2031, such that the adjacent conductive pads 202 do not interfere with each other.

In some embodiments, the first preset value ranges from 30 μm to 60 μm. Within this range, the plurality of first openings 2031 in the first organic insulating layer 203 are in one-to-one correspondence with the plurality of conductive pads 202.

In an exemplary embodiment, when the minimum distance L3 between two adjacent second openings is greater than 70 μm, the first opening 2031 corresponds to one conductive pad 202.

The distance L4 between the edge of the orthographic projection of the first opening 2031 on the base substrate 201 and at least a partial edge of the orthographic projection of the corresponding conductive pad 202 on the base substrate 201 is greater than 7 μm.

In some embodiments, as shown in FIG. 4, the minimum distance L2 between the two adjacent conductive pads 202 is less than the first preset value, and the first opening 2031 corresponds to a plurality of conductive pads 202. That is, in the case that the plurality of conductive pads 202 are arranged densely on the display substrate 20, the first organic insulating layer 203 can expose a plurality of conductive pads 202 through one first opening 2031, which can reduce the manufacturing difficulty of the display substrate 20.

It should be noted that due to the process fluctuation in the manufacturing process of the display substrate 20, when the plurality of film layers in the display substrate 20 are designed, the wrapping relationship between the film layers needs to be considered. That is, the distance between the edges of the adjacent film layers needs to be greater than the preset value, to avoid the poor uniformity at the edges of the adjacent film layers.

Exemplarily, as shown in FIG. 3, the film layers at position of the conductive pad 12 includes the conductive pad 12, the first organic insulating layer 13 and the first inorganic insulating layer 14 laminated in the direction going away from the base substrate 11, and the wrapping relationship between the film layers here is: the edge of the first opening 131 in the first organic insulating layer 13 covers the conductive pad 12, and the edge of the second opening 141 in the first inorganic insulating layer 14 is in the first opening 131, that is, the edge of the first opening 131 wraps the edge of the second opening 141.

When the range value of the process fluctuation during manufacturing process of the display substrate is 5 μm, the designed value of the distance between the edges of the plurality of film layers in the display substrate 10 satisfies the following relationship: the distance L5 between the edge of the orthographic projection of the first opening 131 in the first organic insulating layer 13 on the base substrate 11 and the edge of the orthographic projection of the corresponding conductive pad 12 on the base substrate 11 is greater than 7 μm, which can avoid the situation that one part of the edge of the first opening 131 is outside the conductive pad 12 and the other part of the edge is on the conductive pad 12. Thus, the uniformity of the organic insulating layer in the display substrate is better.

The distance L6 between the edge of the orthographic projection of the second opening 141 in the first inorganic insulating layer 14 on the base substrate 11 and the edge of the orthographic projection of the first opening 131 in the first organic insulating layer 13 on the base substrate 11 is greater than 9 μm, which can avoid the situation that the first inorganic insulating layer 14 can cover the first organic insulating layer 13 at a partial periphery of the first inorganic insulating layer 14, but cannot cover the first organic insulating layer 13 at another partial periphery of the first inorganic insulating layer 14. Therefore, the uniformity of the film layers in the display substrate is better. In the case that the uniformity of the film layers in the region of the conductive pad 12 is better, the distance between the edge of the orthographic projection of the second opening 141 on the base substrate 11 and the edge of the orthographic projection of the conductive pad 12 on the base substrate 11 is greater than 16 μm.

However, as can be seen from FIG. 1, in the related art, the distance L7 between the edges of two adjacent conductive pads 12 along a first direction f1 is 10.5 μm, and the distance (L5+L6) between the edge of the orthographic projection of the second opening 141 on the base substrate 11 and the edge of the orthographic projection of the conductive pad 12 on the base substrate 11 is 11 μm. Thus, the distance between the edges of two adjacent second openings 141 along the first direction is 32.5 μm (11×2+10.5=32.5).

If the size of the conductive pad 12 is adjusted so that the distance between the edge of the conductive pad 12 and the edge of the second opening 141 is 16 μm, the distance between the edges of two adjacent conductive pads 12 along the first direction is 0.5 μm. As a result, the distance between the two conductive pads 12 is short, which easily results in a short circuit between the adjacent conductive pads 12.

Alternatively, in an optional embodiment, the distance between two adjacent conductive pads 12 is greater than 14 μm, for example, 18 μm. If the first opening 131 is enlarged such that the orthographic projection of the edge of the first opening 131 on the base substrate 11 is outside the orthographic projection of the edge of the corresponding conductive pad 12 on the base substrate 11, and the distance between the edge of the orthographic projection of the first opening 131 on the base substrate 11 and the edge of the orthographic projection of the corresponding conductive pad 12 on the base substrate 11 is greater than 7 μm, the minimum distance between the edge of the orthographic projection of the first opening 131 on the base substrate 11 and the edge of the orthographic projection of the second opening 141 on the base substrate 11 is greater than 9 μm. Because the distance between the first openings 131 corresponding to two adjacent conductive pads 12 is short, it is difficult to manufacture the first organic insulating layer 13, thereby resulting in a low yield of the display substrate.

Thus, in the embodiments of the present disclosure, by setting one first opening 2031 to correspond to a plurality of conductive pads 202, the distance between the first organic insulating layer 203 and the pad region 202a of the conductive pad 202 exposed from the second opening 2041 is increased, under the premise of ensuring the good uniformity of the plurality of film layers in the display substrate. Thus, the coverage effect of the first inorganic insulating layer 204 on the first organic insulating layer 203 is improved.

In some embodiments, FIG. 10 is a schematic structural diagram of another display substrate according to some embodiments of the present disclosure. Referring to FIG. 10, the plurality of conductive pads 202 include a plurality of first conductive pads 2021 and a plurality of second conductive pads 2022. Every two first conductive pads 2021 constitute one first conductive pad group 2021a, and one first conductive pad group 2021a is configured to be connected to one light-emitting device. Every N second conductive pads 2022 constitute one second conductive pad group 2022a, and one second conductive pad group 2022a is configured to be connected to one driver chip. Here, N is a positive integer greater than or equal to 2, for example, N is 6.

The first opening 2031 includes a first sub-opening 20311 and a second sub-opening 20312. The first sub-opening 20311 corresponds to one first conductive pad group 2021a and the second sub-opening 20312 corresponds to one second conductive pad group 2022a.

The distance between two adjacent first conductive pads 2021 of the plurality of first conductive pads 2021 along a second direction f2 is greater than the distance between two adjacent first conductive pads 2021 of the plurality of first conductive pads 2021 along the first direction f1. Exemplarily, the distance between two adjacent second openings 2041 of the plurality of second openings 2041 along the second direction f2 is 86 μm, and the distance L2 between two adjacent conductive pads 202 of the plurality of conductive pads 202 along the second direction f2 is 58 μm. Therefore, the first organic insulating layer 203 is located in the region between two adjacent second openings 2041 along the second direction f2, and in the second direction f2, the distance between the edge of the orthographic projection of the first opening 2031 on the base substrate 201 and the orthographic projection of each of the corresponding two conductive pads 202 on the base substrate 201 is greater than 7 μm. Exemplarily, the distance between two adjacent second openings 2041 of the plurality of second openings 2041 along the first direction f1 is 46 μm, and the distance L8 between two adjacent first conductive pads 2021 of the plurality of first conductive pads 2021 along the first direction f1 is 18 μm. Therefore, the first organic insulating layer 203 is not located in the region between two adjacent conductive pads 202 along the first direction f1, to avoid the poor uniformity of the first organic insulating layer 203.

Similarly, compared with the plurality of first conductive pads 2021, in the plurality of second conductive pads 2022 that are densely arranged, six second conductive pads 2022 correspond to one first opening 2031, which can increase the distance between the first opening 2031 and the second opening 2041, thereby increasing the distance between the first organic insulating layer 203 and the conductive pad 202 exposed from the second opening 2041. Thus, the manufacturing difficulty of the display substrate 20 is reduced, the uniformity of the first organic insulating layer 203 is improved, and the yield of the display substrate 20 is improved.

Exemplarily, each light-emitting device includes two pins, and each driver chip includes six pins. The two pins of each light-emitting device are electrically connected to two first conductive pads 2021 through two second openings 2041 passing through the first inorganic insulating layer 204 and one first sub-opening 20311 passing through the first organic insulating layer 203.

The six pins of each driver chip are electrically connected to six second conductive pads 2022 through six second openings 2041 passing through the first inorganic insulating layer 204 and one second sub-opening 20312 passing through the first organic insulating layer 203, thereby controlling the light-emitting device to emit light through the driver chip.

In some embodiments, as shown in FIG. 4, the plurality of conductive pads 202 include a plurality of first conductive pads 2021 and a plurality of second conductive pads 2022. Every two first conductive pads 2021 constitute one first conductive pad group (not shown in the figure), and one first conductive pad group is configured to be connected to one light-emitting device. Every N second conductive pads 2022 constitute one second conductive pad group (not shown in the figure), and one second conductive pad group is configured to be connected to one driver chip. Here, N is a positive integer greater than or equal to 2, for example, N is 6.

The first openings 2031 include a first sub-opening 20311 and a second sub-opening 20312. The first sub-opening 20311 corresponds to at least three adjacent first conductive pad groups, and the second sub-opening 20312 corresponds to one second conductive pad group. It should be noted that the division of the first conductive pad group and the second conductive pad group in FIG. 4 is the same as that of the first conductive pad group and the second conductive pad group in FIG. 10.

Exemplarily, the plurality of light-emitting devices include a blue light-emitting device for emitting blue light, a green light-emitting device for emitting green light, and a red light-emitting device for emitting red light. Each light-emitting device includes two pins, the two pins of each light-emitting device are electrically connected to the first conductive pads 2021 through two second openings 2041 passing through the first inorganic insulating layer 204, and the six pins of the three light-emitting devices are electrically connected to the first conductive pads 2021 through one first sub-opening 20311 passing through the first organic insulating layer 203.

Each driver chip includes six pins, and the six pins of each driver chip are electrically connected to six second conductive pads 2022 through six second openings 2041 passing through the first inorganic insulating layer 204 and one second sub-opening 20312 passing through the first organic insulating layer 203, thereby controlling the light-emitting device through the driver chip.

In some embodiments, as shown in FIG. 4, the distance between the first sub-opening 20311 and the second sub-opening 20312 adjacent to each other ranges from 20 μm to 100 μm, that is, the distance L9 between the first sub-opening 20311 corresponding to the first conductive pad group and the second sub-opening 20312 corresponding to the second conductive pad group may be greater than 20 μm, thereby reducing the influence between the plurality of first conductive pads 2021 and the plurality of second conductive pads 2022.

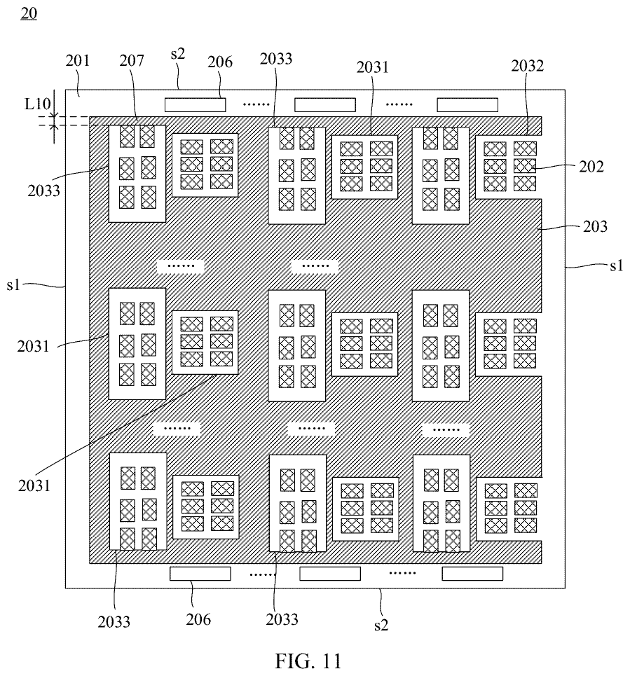

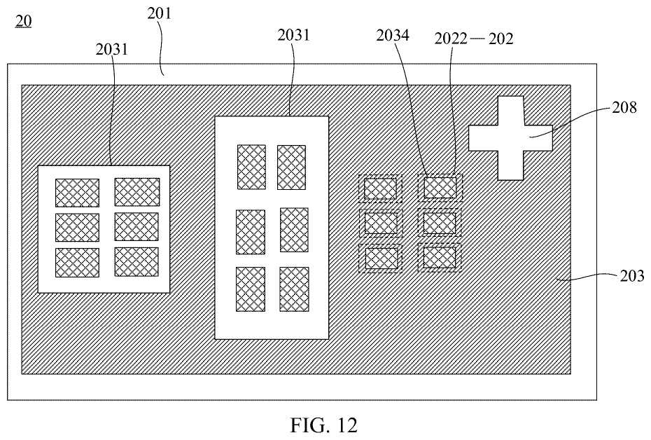

In some embodiments, FIG. 11 shows another display substrate 20 according to some embodiments of the present disclosure. Referring to FIG. 11, the display substrate 20 is rectangular, and the display substrate 20 has two opposite first edges s1 and two opposite second edges s2. The display substrate 20 further includes connection terminals 206 and side wires (not shown in the figure) which are located at the second edges s2. The connection terminal 206 and the side wire are electrically connected to each other. The connection terminals 206 are located in a region, exposed from the first organic insulating layer 203 and the first inorganic insulating layer 204, of the second edge s2 of the display substrate 20.

The plurality of first openings 2031 include a target first opening 2032, the target first opening 2032 is adjacent to the first edge s1, and an edge of the target first opening 2032 coincides with an edge of the first organic insulating layer 203 at the first edge s1. The display substrate 20 is obtained by cutting a display substrate motherboard, which includes a plurality of connected display substrates 20. After cutting the display substrate motherboard, independent display substrates 20 are obtained. In the manufacturing process of the display substrate 20, the display substrate motherboard is cut by using lasers with higher energy, to cut the display substrate motherboard into a plurality of display substrates 20.

There is a cutting area on the display substrate motherboard, and the cutting area is referred to as a cutting channel. The edge of the cutting area is the edge of the first organic insulating layer 203 in each display substrate 20. When lasers are used to cut the display substrate motherboard along the cutting area of the display substrate motherboard, under the effect of the high energy lasers, the first organic insulating layer 203 at the edge of the display substrate 20 will be fused to generate carbonized foreign matter, resulting in a low yield of the display substrate. Therefore, by not covering the cutting area of the display substrate motherboard with the first organic insulating layer 203, the carbonized foreign matter can be prevented from generating when the display substrate motherboard is cut. The edge of the target first opening 2032 coincides with the edge of the first organic insulating layer 203 at the first edge s1, that is, the target first opening 2032 and the cutting channel are communicated, which can simplify the manufacturing difficulty of the display substrate 20.

In some embodiments, as shown in FIG. 11, the first organic insulating layer 203 is also provided with a third opening 2033, and the third opening 2033 is adjacent to the second edge s2. The side face of the display substrate 20 at the second edge s2 of the display substrate 20 is configured to be provided with side wires, and the side wires are configured to connect front wires and back wires of the display substrate 20. The wires at the display side of the display device and the circuit board (e.g., a flexible circuit board) disposed at the non-display side of the display substrate are connected by the side wires, to reduce the border size of smaller display device and reduce the spacing between adjacent smaller display devices.

The third opening 2033 corresponds to at least one conducting pad 202, and the edge of the orthographic projection of the third opening 2033 on the base substrate 201 is at least partially outside the orthographic projection of at least one corresponding conducting pad 202 on the base substrate 201. There is a second preset distance L10 between the edge of the third opening 2033 and the edge, located at the second edge s2, of the first organic insulating layer 203. In the manufacturing process of display substrate 20, the front wires and the back wires are manufactured by exposure, the side wires are manufactured by a laser etching process, and a large amount of heat is generated when the side wires are manufactured by the laser etching process. Therefore, in the embodiments of the present disclosure, by setting a second preset distance between the edge of the third opening 2033 and the edge, located at the second edge s2, of the first organic insulating layer 203, a partial structure of the first organic insulating layer 203 is present between the edge of the third opening 2033 and the edge of the first organic insulating layer 203. The partial structure is referred to as a barrier wall 207. The barrier wall 207 is configured to insulate the heat caused by laser etching of the side wires to avoid the heat from affecting the conductive pad 202 in the third opening 2033.

In some embodiments, the second preset distance ranges from 20 μm to 50 μm. In this range, the barrier wall 207 has a better insulation effect. Furthermore, the third opening 2033 corresponds to at least one second opening, and the orthographic projection of the at least one second opening on the base substrate 201 is within the orthographic projection of the corresponding third opening 2033 on the base substrate 201. This range has a smaller influence on the distance between the edge of the orthographic projection of the third opening 2033 on the base substrate 201 and the edge of the orthographic projection of the second opening on the base substrate 201, which can prevent the first inorganic insulating layer 204 from exposing the first organic insulating layer 203. Exemplarily, the minimum distance between the edge of the orthographic projection of the third opening 2033 on the base substrate 201 and the edge of the orthographic projection of the corresponding at least one second opening on the base substrate 201 is greater than 10 μm.

In some embodiments, FIG. 12 shows another display substrate 20 according to some embodiments of the present disclosure. With reference to FIG. 12, the display substrate 20 is further provided with an alignment mark 208, which is configured to align an exposure device when patterns of the film layers in the display substrate 20 are formed by exposure. The first organic insulating layer 203 is further provided with a fourth opening 2034. The fourth opening 2034 is adjacent to the alignment mark 208, the fourth opening 2034 corresponds to one conductive pad 202, and the orthographic projection of the fourth opening 2034 on the base substrate 201 is within the orthographic projection of the corresponding conductive pad 202 on the base substrate 201. The second openings (not shown in FIG. 12) and the fourth openings 2034 are in one-to-one correspondence, and the orthographic projection of the second opening on the base substrate 201 is within the orthographic projection of the fourth opening 2034 on the base substrate 201. In this way, the size of the fourth opening 2034 is smaller, which can prevent the fourth opening 2034 from affecting the alignment mark 208.

Exemplarily, the conductive pad 202 corresponding to the fourth opening 2034 is the second conductive pad 2022, i.e., the conductive pad 202 connected to the driver chip.

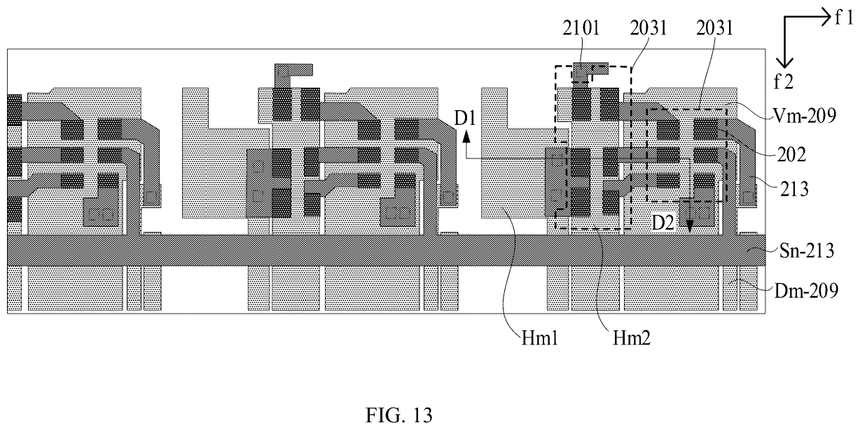

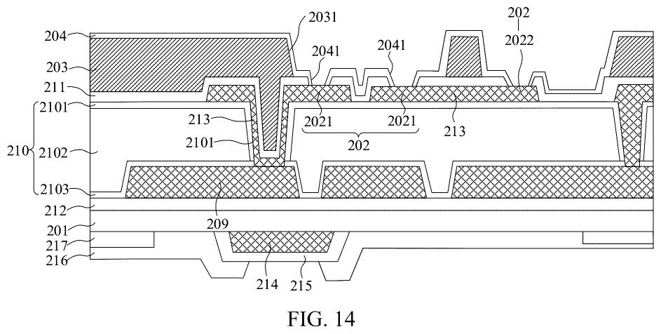

In some embodiments, FIG. 13 shows another display substrate 20 according to some embodiments of the present disclosure, and FIG. 14 is a cross-sectional structural diagram of the display substrate 20 as shown in FIG. 13 along a position D1-D2. Referring to FIG. 13 and FIG. 14, the display substrate 20 further includes a first wiring pattern 209 and a second insulating layer 210 which are disposed between the plurality of conductive pads 202 and the base substrate 201. The first wiring pattern 209 and the second insulating layer 210 are laminated along the direction going away from the base substrate 201. The second insulating layer 210 has a via hole 2101, and the orthographic projection of the via hole 2101 on the base substrate 201 at least partially overlaps with the orthographic projection of the first wiring pattern 209 on the base substrate 201.

The display substrate 20 further includes a second wiring pattern 213 which is disposed in the same layer as the plurality of conductive pads 202 and electrically connected to the plurality of conductive pads 202. The second wiring pattern 213 is electrically connected to the first wiring pattern 209 through the via hole 2101. The base substrate 201 may further include a buffer layer disposed between the first wiring pattern 209 and the display substrate 20. The first wiring pattern 209 includes a plurality of first signal lines. The second insulating layer 210 is disposed on the side of the first wiring pattern 209 away from the base substrate 201. The plurality of conductive pads 202 and the second wiring pattern 213 are disposed on the side of the second insulating layer 210 away from the base substrate 201, and the second wiring pattern 213 includes a plurality of second signal lines. It is understood that the conductive pad 202 and the second wiring pattern 213 in direct contact with the conductive pad 202 are integrated. In some embodiments, the conductive pad 202 and the first wiring pattern 209 are integrated.

The plurality of second signal lines include a plurality of data signal lines Dm a plurality of first positive signal lines Hm1, a plurality of second positive signal lines Hm2, a plurality of reference signal lines Vm, and a plurality of scan signal connection lines which all are extended along the second direction f2. The second wiring pattern 213 includes a plurality of scan signal lines Sn. The scan signal line Sn is electrically connected to the scan signal connection line, and the scan signal line Sn is extended along the first direction f1. Exemplarily, in a plurality of pixels arranged in an array (for example, each pixel includes three light-emitting devices arranged in the second direction f2 and a driver chip configured to provide signals for the three light-emitting devices), each row of pixels is electrically connected to the same scan signal line Sn, and each row of pixels is electrically connected to one data signal line Dm, one reference signal line Vm, one first positive signal line Hm1 and one second positive signal line Hm2, to achieve reasonable wiring and transmit corresponding signals to the pixels through the plurality of signal lines.

The edge of the orthographic projection of the first opening 2031 on the base substrate 201 is staggered from the edge of the orthographic projection of the via hole 2101 on the base substrate 201, which can have the following two effects. On the one hand, the via hole 2101 is protected by the first organic insulating layer 203; and on the other hand, the first inorganic insulating layer 204 is prevented from rising and falling greatly at the via hole 2101, thereby preventing the first inorganic insulating layer 204 from fracturing.

Exemplarily, the minimum distance between the edge of the orthographic projection of the via hole 2101 on the base substrate 201 and the edge of the orthographic projection of the first opening 2031 on the base substrate 201 is greater than or equal to 10 μm.

In some embodiments, as shown in FIG. 14, the second insulating layer 210 includes a fourth inorganic insulating layer 2103, a second organic insulating layer 2102 and a third inorganic insulating layer 2101 which are laminated. The display substrate further includes a second inorganic insulating layer 211 disposed on the side of the first organic insulating layer 203 facing the base substrate 201. The second inorganic insulating layer 211 is provided with an opening at a position which is overlapped with the position of the second opening in the first inorganic insulating layer 204, and the second inorganic insulating layer 211 and the first inorganic insulating layer 204 are formed by a single patterning process.

The display substrate further includes a buffer layer 212 disposed on the side of the first wiring pattern 209 facing the base substrate 201, and a third wiring pattern 214, a wire protective layer 215 and a fifth inorganic insulating layer 216 which are disposed on the side of the base substrate 201 facing away from the buffer layer 212 and are laminated in a direction going away from the base substrate 201. The third wiring pattern 214 is a circuit that connects the side wires and a drive control device on the back of the display substrate. The wire protective layer 215 is made from indium tin oxide, to prevent the third wiring pattern 214 from being eroded by moisture. A backside mark 217 is further provided between the base substrate 210 and the fifth inorganic insulating layer 216, and the backside mark 217 is used as an alignment mark.

In summary, the embodiments of the present disclosure provide a display substrate, including a base substrate, a plurality of conductive pads, a first organic insulating layer, and a first inorganic insulating layer. The first organic insulating layer is provided with a first opening corresponding to at least one conductive pad, and the first inorganic insulating layer is provided with a second opening corresponding to the conductive pad. The orthographic projection of at least one conductive pad on the base substrate is within the orthographic projection of the corresponding first opening on the base substrate, and the orthographic projection of the second opening on the base substrate is within the orthographic projection of the corresponding conductive pad on the base substrate. Compared with the solution in the related art where the orthographic projection of the first opening on the base substrate is within the orthographic projection of the corresponding conductive pad on the base substrate, the distance between the edge of the first opening and the edge of the second opening in the embodiments of the present disclosure is larger, that is, the distance between the first organic insulating layer and the pad region of the conductive pad exposed from the second opening is increased, which can prevent the first organic insulating layer from affecting the metal plating layer in the pad region of the conductive pad exposed from the second opening. Therefore, the problem of the low yield of the display substrate in related art can be solved, and the yield of the display substrate can be improved.

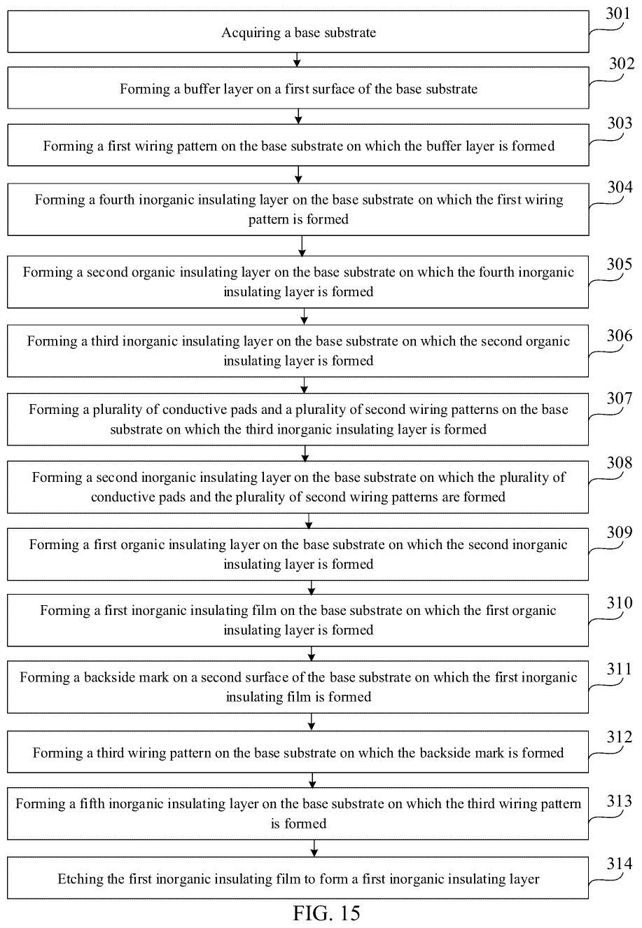

FIG. 15 is a flowchart of a method for manufacturing a display substrate according to some embodiments of the present disclosure. The method is applicable to manufacturing the display substrate provided in the above embodiments, such as the display substrate 20 as shown in FIG. 14 in the above embodiments. With reference to FIG. 15, the method includes the following steps.

In step 301, a base substrate is acquired.

In some embodiments, the base substrate is a flexible substrate. The flexible substrate is made of a flexible material (e.g., polyimide PI material). Alternatively, the base substrate is a glass substrate. Alternatively, the base substrate is a non-light-transmitting substrate.

In step 302, a buffer layer is formed on a first surface of the base substrate.

After the base substrate is cleaned using a standard method, a buffer layer is formed on the base substrate by a sputtering deposition process. The thickness of the buffer layer ranges from 1500 Å to 2600 Å, and the material of the buffer layer includes at least one of silicon oxide (SiOx) or nitrogen oxide (SiNx).

In step 303, a first wiring pattern is formed on the base substrate on which the buffer layer is formed.

A first metal material film is formed on the side of the buffer layer away from the base substrate by the sputtering deposition process or an atomic layer deposition (ALD) process, and then the first metal material film is patterned to acquire the first wiring pattern. The thickness of the first wiring pattern ranges from 2000 Å to 3000 Å, and the material of the first wiring pattern includes at least one of metals such as copper (Cu) and molybdenum-niobium alloys (MoNb). Alternatively, the first wiring pattern is a laminated structure of molybdenum-niobium alloys, copper and molybdenum-niobium alloys (MoNb/Cu/MoNb).

The steps of the patterning process include at least part of cleaning, coating, baking, exposure, development, hard baking, etching, stripping and other processes.

In step 304, a fourth inorganic insulating layer is formed on the base substrate on which the first wiring pattern is formed.

The fourth inorganic insulating layer is formed on the base substrate by the sputtering deposition process or a chemical vapor deposition (CVD) process. The thickness of the fourth inorganic insulating layer ranges from 2200 Å to 2600 Å, and the material of the fourth inorganic insulating layer includes at least one of silicon oxide (SiOx) or nitrogen oxide (SiNx). The fourth inorganic insulating layer is provided with a first via hole, and the orthographic projection of the first via hole on the base substrate is overlapped with the orthographic projection of the first wiring pattern on the base substrate.

In step 305, a second organic insulating layer is formed on the base substrate on which the fourth inorganic insulating layer is formed.

The second organic insulating layer is formed on the side of the fourth inorganic insulating layer away from the base substrate by coating, exposure, and development and other processes. The thickness of the second organic insulating layer ranges from 3.5 μm to 7.5 μm. The second organic insulating layer is provided with a second via hole, the orthographic projection of the second via hole on the base substrate is overlapped with the orthographic projection of the first wiring pattern on the base substrate, and the second via hole is communicated with the first via hole.

In some embodiments, the material of the second organic insulating layer includes an organic insulating material, for example, at least one of polyimide, optical clear adhesive and polyamide.

In step 306, a third inorganic insulating layer is formed on the base substrate on which the second organic insulating layer is formed.

The third inorganic insulating layer is formed on the base substrate by the sputtering deposition process or the chemical vapor deposition (CVD) process. The thickness of the third inorganic insulating layer ranges from 1200 Å to 3300 Å, and the material of the third inorganic insulating layer includes at least one of silicon oxide (SiOx) or nitrogen oxide (SiNx). The third inorganic insulating layer is provided with a third via hole, the orthographic projection of the third via hole on the base substrate is overlapped with the orthographic projection of the first wiring pattern on the base substrate, and the third via hole is communicated with the first via hole and the second via hole.

In an optional embodiment, the process of forming the above three via holes includes: forming the second via hole in the second organic insulating layer first, and then etching the parts of the third inorganic insulating layer and the fourth inorganic insulating layer which are at the second via hole by a single dry etching process to form the first via hole and the third via hole by the single etching process.

In step 307, a plurality of conductive pads and a plurality of second wiring patterns are formed on the base substrate on which the third inorganic insulating layer is formed.

A second metal material film is formed on the side of the third inorganic insulating layer away from the base substrate by the sputtering deposition process or the atomic layer deposition (ALD) process, and then the second metal material film is patterned to acquire the second wiring patterns and the plurality of conductive pads. The thicknesses of the second wiring pattern and the conductive pad range from 0.8 μm to 1 μm. For example, the thicknesses of the second wiring pattern and the conductive pad are 0.9 μm, and the materials of the second wiring pattern and the conductive pad include at least one of metals such as copper (Cu) and molybdenum-niobium alloys (MoNb). Alternatively, each of the first wiring pattern and conductive pad is a laminated structure of molybdenum niobium alloys, copper and molybdenum niobium alloys (MoNb/Cu/MoNb).

In step 308, a second inorganic insulating layer is formed on the base substrate on which the plurality of conductive pads and the plurality of second wiring patterns are formed.

The second inorganic insulating layer is formed on the base substrate by the sputtering deposition process or the chemical vapor deposition (CVD) process. The thickness of the second inorganic insulating layer ranges from 1200 Å to 2600 Å, and the material of the second inorganic insulating layer includes at least one of silicon oxide (SiOx) or nitrogen oxide (SiNx). The second inorganic insulating layer is provided with a fifth opening, the fifth opening penetrates through the second inorganic insulating layer, and the orthographic projection of the fifth opening on the base substrate is within the orthographic projection of the conductive pad on the base substrate.

In step 309, a first organic insulating layer is formed on the base substrate on which the second inorganic insulating layer is formed.

The first organic insulating layer is formed on the side of the second inorganic insulating layer away from the base substrate by coating, exposure, development and the like. The thickness of the first organic insulating layer ranges from 1.5 μm to 2.5 μm. The first organic insulating layer is provided with a first opening, and the first opening penetrates through the first organic insulating layer. The first organic insulating layer corresponds to at least one conductive pad, that is, the orthographic projection of at least one conductive pad on the base substrate is within the orthographic projection of the first opening on the base substrate. Moreover, the orthographic projection of at least one third opening on the base substrate is within the orthographic projection of the first opening on the base substrate. In some embodiments, the material of the first organic insulating layer includes an organic insulating materials, and includes at least one of polyimide, optical clear adhesive and polyamide.

In step 310, a first inorganic insulating film is formed on the base substrate on which the first organic insulating layer is formed.

The first inorganic insulating film is formed on the base substrate by the sputtering deposition process or the chemical vapor deposition (CVD) process. The thickness of the first inorganic insulating film ranges from 1200 Å to 3300 Å, and the material of the first inorganic insulating film includes at least one of silicon oxide (SiOx) or nitrogen oxide (SiNx). In this step, the first inorganic insulating film can completely cover the film layer structure under the first inorganic insulating film.

In some embodiments, after the first inorganic insulating film is formed on the base substrate, the base substrate on which the first inorganic insulating film is formed is cut to form a plurality of display substrates, and then an electroless gold plating process is performed on a plurality of pad regions on the base substrate (i.e., the regions of the conductive pads which are exposed) to prevent the pad regions from corrosion and oxidation.

In step 311, a backside mark is formed on a second surface of the base substrate on which the first inorganic insulating film is formed.

After the first inorganic insulating film is formed on the first surface of the display substrate, the display substrate is turned over for the first time, and the backside mark (OC Mark) is formed on the second surface of the base substrate by coating, exposure, development and other processes.

In step 312, a third wiring pattern is formed on the base substrate on which the backside mark is formed.

The third wiring pattern is formed by the sputtering deposition process, cleaning, coating, baking, exposure, development, hard baking, etching, stripping and other processes. The thickness of the third wiring pattern ranges from 8000 Å to 9500 Å, and the material of the third wiring pattern includes at least one of metals such as copper (Cu) and molybdenum-niobium alloys (MoNb). Alternatively, the third wiring pattern is a laminated structure of molybdenum-niobium alloys, copper and molybdenum-niobium alloys (MoNb/Cu/MoNb).

A wire protective layer is further formed on the side of the third wiring pattern away from the base substrate. The wire protective layer covers the third wiring pattern to protect the third wiring pattern. The material of the wire protective layer includes indium tin oxide (ITO), and the thickness of the wire protective layer ranges from 500 Å to 600 Å. For example, the thickness of the wire protective layer is 520 Å.

In step 313, a fifth inorganic insulating layer is formed on the base substrate on which the third wiring pattern is formed.

The fifth inorganic insulating layer is formed on the base substrate by the sputtering deposition process or the chemical vapor deposition (CVD) process. The thickness of the fifth inorganic insulating layer ranges from 5000 Å to 6000 Å, and the material of the fifth inorganic insulating layer includes at least one of silicon oxide (SiOx) or nitrogen oxide (SiNx). The fifth inorganic insulating layer is provided with a sixth opening, and the orthographic projection of the sixth opening on the base substrate is overlapped with the orthographic projection of the third wiring pattern on the base substrate. The third wiring pattern is electrically connected to the side wires, the flexible circuit board and other structures through the sixth opening.

In step 314, the first inorganic insulating film is etched to form a first inorganic insulating layer.

After the fifth inorganic insulating layer is formed on the second surface of the display substrate, the display substrate is turned over for a second time, and the first inorganic insulating layer is formed by the dry etching process.

The first inorganic insulating layer is provided with a second opening, and the orthographic projection of the second opening on the base substrate is within the orthographic projection of the conductive pad on the base substrate. The first opening and the fifth opening are within the second opening.

In an optional embodiment, the process of forming the above three openings includes: forming the first opening in the first organic insulating layer first, and then etching the parts of the first inorganic insulating layer and the second inorganic insulating layer which are at the second opening by a single dry etching process to form the second opening and the fifth opening by the single etching process.

In summary, the embodiments of the present disclosure provide a method for manufacturing a display substrate. The display substrate includes a base substrate, a plurality of conductive pads, a first organic insulating layer, and a first inorganic insulating layer. The first organic insulating layer is provided with a first opening corresponding to at least one conductive pad, and the first inorganic insulating layer is provided with a second opening corresponding to the conductive pad. The orthographic projection of at least one conductive pad on the base substrate is within the orthographic projection of the corresponding first opening on the base substrate, and the orthographic projection of the second opening on the base substrate is within the orthographic projection of the corresponding conductive pad on the base substrate. Compared with the solution in the related art where the orthographic projection of the first opening on the base substrate is within the orthographic projection of the corresponding conductive pad on the base substrate, the distance between the edge of the first opening and the edge of the second opening in the embodiments of the present disclosure is larger, that is, the distance between the first organic insulating layer and the pad region of the conductive pad exposed from the second opening is increased, which can prevent the first organic insulating layer from affecting the metal plating layer in the pad region of the conductive pad exposed from the second opening. Therefore, the problem of the low yield of the display substrate in related art can be solved, and the yield of the display substrate can be improved.

The embodiments of the present disclosure further provide a display device, which includes the display substrate in any one of the above embodiments. The light-emitting device in the display substrate includes an organic light-emitting diode (OLED), a mini light-emitting diode (Mini LED), a micro light-emitting diode (Micro LED) and the like.

Compared with the traditional LED, as a light-emitting device, the mini LED or micro LED occupies a smaller volume, has smaller particles, and has a higher light source density in unit area on the screen of the same size, and the light source has a smaller unit size. Thus, a precise local control over the light-emitting device can be achieved, and the problem of non-uniform brightness of the light-emitting devices will not occur, thereby ensuring the uniformity of display brightness and the display quality of the display device.

In some embodiments, the display device further includes an integrated circuit chip and a flexible circuit board.

Exemplarily, the integrated circuit chip is configured to be electrically connected to the flexible circuit board, the integrated circuit chip sends out a control signal, and the flexible circuit board transmits the drive signal acquired based on the control signal to the side wires and a connection terminal. The connection terminal is electrically connected to the plurality of the first signal lines in the first wiring pattern, and the plurality of the first signal lines are electrically connected to the plurality of conductive pads via the second wiring pattern, so as to transmit the drive signal to the plurality of conductive pads. The plurality of conductive pads then transmit the drive signal to the light-emitting device to control the light-emitting device to emit light, and thus the display device displays images.

The display device further includes a driver chip. It is understood that the plurality of first signal lines in the first wiring pattern are further electrically connected to the driver chip, to enable the driver chip to control the luminous brightness of the light-emitting device. Specifically, three light-emitting devices are controlled by one driver chip, or four, five or more light-emitting devices are controlled by one driver chip, which is not limited in the present embodiments of the present disclosure.

In an optional embodiment, the display device includes a plurality of display substrates in any one of the above embodiments, and the plurality of display substrates in the display device are arranged in an array.

The term “at least one of A and B” in the present disclosure merely describes an association relationship among associated objects, indicating three kinds of relationships. For example, at least one of A and B expresses three kinds of relationships: A exists alone, A and B exist simultaneously, and B exists alone. Similarly, “at least one of A, B and C” expresses seven kinds of relationships: A exists alone, B exists alone, C exists alone, A and B exist simultaneously, A and C exist simultaneously, C and B exist simultaneously, and A, B and C exist simultaneously. Similarly, “at least one of A, B, C, and D” expresses fifteen kinds of relationships: A exists alone, B exists alone, C exists alone, D exists alone, A and B exist simultaneously, A and C exist simultaneously, A and D exist simultaneously, C and B exist simultaneously, D and B exist simultaneously, C and D exist simultaneously, A, B and C exist simultaneously, A, B and D exist simultaneously, A, C and D exist simultaneously, B, C and D exist simultaneously, and A, B, C and D exist simultaneously.

It should be noted that, in the accompanying drawings, the dimensions of layers and regions may be exaggerated for the clarity of illustration. It is also understood that when an element or layer is referred to as being “on” another element or layer, the element or layer may be directly on the other element or an intermediate layer may exist. In addition, it is understood that when an element or layer is referred to as being “under” another element or layer, the element or layer may be directly under the another element or more than one intermediate layer or element may exist. It is further understood that when a layer or element is referred to as being “between” two layers or two elements, the layer or element may be the only layer between the two layers or two elements, or there may also be more than one intermediate layer or element. Similar reference numerals throughout indicate similar elements.

In the present disclosure, the terms “first”, “second”, “third” and “fourth” are used for descriptive purposes only and shall not be construed as indicating or implying any relative importance. The term “a plurality of” means two or more, unless otherwise expressly specified.

The foregoing descriptions are merely optional embodiments of the present disclosure and are not intended to limit the present disclosure. Any modifications, equivalent replacements, improvements and the like within the spirit and principles of the present disclosure shall be included within the protection scope of the present disclosure.

1. A display substrate, comprising:
a base substrate;
a plurality of conductive pads disposed on the base substrate;
a first organic insulating layer disposed on the base substrate provided with the conductive pads, wherein the first organic insulating layer is provided with a plurality of first openings, the first opening corresponds to at least one conductive pad, and an orthographic projection of the at least one conductive pad on the base substrate is within an orthographic projection of the corresponding first opening on the base substrate; and
a first inorganic insulating layer disposed on a side of the first organic insulating layer facing away from the base substrate, wherein the first inorganic insulating layer is provided with a plurality of second openings, the second opening corresponds to the conductive pad, and an orthographic projection of the second opening on the base substrate is within an orthographic projection of the corresponding conductive pad on the base substrate.

2. The display substrate according to claim 1, further comprising: a conductive anti-oxidation layer, wherein the conductive anti-oxidation layer is disposed on the base substrate provided with the first inorganic insulating layer, an orthographic projection of the conductive anti-oxidation layer on the base substrate is within an orthographic projection of the second opening on the base substrate, and the conductive anti-oxidation layer covers a surface, away from the base substrate, of a pad region of the conductive pad, the pad region being a region of the conductive pad which is exposed from the second opening.

3. The display substrate according to claim 1, wherein a minimum distance between two adjacent conductive pads is greater than or equal to a first preset value, and the first opening corresponds to one conductive pad.

4. The display substrate according to claim 1, wherein a minimum distance between two adjacent conductive pads is less than a first preset value, and the first opening corresponds to a plurality of conductive pads.

5. The display substrate according to claim 3, wherein the first preset value ranges from 30 μm to 60 μm.

6. The display substrate according to claim 1, wherein the plurality of conductive pads comprise a plurality of first conductive pads and a plurality of second conductive pads; wherein
every two first conductive pads constitute one first conductive pad group, and one first conductive pad group is configured to be connected to one light-emitting device;
every N second conductive pads constitute one second conductive pad group, and one second conductive pad group is configured to be connected to one driver chip; and
the first openings comprise a first sub-opening and a second sub-opening, wherein the first sub-opening corresponds to one first conductive pad group, and the second sub-opening corresponds to one second conductive pad group.

7. The display substrate according to claim 1, wherein the plurality of conductive pads comprise a plurality of first conductive pads and a plurality of second conductive pads; wherein
every two first conductive pads constitute one first conductive pad group, and one first conductive pad group is configured to be connected to one light-emitting device;
every N second conductive pads constitute one second conductive pad group, and each second conductive pad group is configured to be connected to one driver chip; and
the first openings comprise a first sub-opening and a second sub-opening, wherein the first sub-opening corresponds to at least three adjacent first conductive pad groups, and the second sub-opening corresponds to one second conductive pad group.

8. The display substrate according to claim 6, wherein a distance between the first sub-opening and the second sub-opening which are adjacent to each other ranges from 20 μm to 100 μm.

9. The display substrate according to claim 1, wherein
the first opening corresponds to at least one second opening, and an orthographic projection of the at least one second opening on the base substrate is within an orthographic projection of the corresponding first opening on the base substrate; and
a minimum distance between an edge of the orthographic projection of the first opening on the substrate and an edge of the orthographic projection of the at least one second opening on the base substrate ranges from 20 am to 80 μm.

10. The display substrate according to claim 1, wherein the display substrate is rectangular and the display substrate has two opposite first edges and two opposite second edges;
the display substrate further comprises connection terminals and side wires which are located at the second edges, the connection terminal and the side wire are electrically connected to each other;
the plurality of first openings comprise a target first opening, wherein the target first opening is adjacent to the first edge, and an edge of the target first opening coincides with an edge, which is located at the first edge, of the first organic insulating layer.

11. The display substrate according to claim 10, wherein the first organic insulating layer is further provided with a third opening; wherein
the third opening is adjacent to the second edge and corresponds to at least one conductive pad, and an edge of an orthographic projection of the third opening on the base substrate is at least partially outside an orthographic projection of the corresponding at least one conductive pad on the base substrate; and
there is a second preset distance between an edge of the third opening and an edge, which is located at the second edge, of the first organic insulating layer.

12. The display substrate according to claim 11, wherein the second preset distance ranges from 20 μm to 50 μm.

13. The display substrate according to claim 1, wherein the display substrate is further provided with an alignment mark, and the first organic insulating layer is further provided with a fourth opening adjacent to the alignment mark; wherein
the fourth opening corresponds to one conductive pad, and an orthographic projection of the fourth opening on the base substrate is within an orthographic projection of the corresponding conductive pad on the base substrate.

14. The display substrate according to claim 1, further comprising: a first wiring pattern and a second insulating layer which are disposed between the plurality of conductive pads and the base substrate, wherein the first wiring pattern and the second insulating layer are stacked in a direction going away from the base substrate, and the second insulating layer is provided with a via hole, and an orthographic projection of the via hole on the base substrate is at least partially overlapped with an orthographic projection of the first wiring pattern on the base substrate;
the display substrate further comprises a second wiring pattern which is disposed in a same layer as the plurality of conductive pads and electrically connected to the plurality of conductive pads, wherein the second wiring pattern is electrically connected to the first wiring pattern through the via hole;
wherein an edge of an orthographic projection of the first opening on the substrate is staggered with an edge of an orthographic projection of the via hole on the base substrate.

15. A display device, comprising a display substrate, wherein the display substrate comprises:
a base substrate;
a plurality of conductive pads disposed on the base substrate;
a first organic insulating layer disposed on the base substrate provided with the conductive pads, wherein the first organic insulating layer is provided with a plurality of first openings, the first opening corresponds to at least one conductive pad, and an orthographic projection of the at least one conductive pad on the base substrate is within an orthographic projection of the corresponding first opening on the base substrate; and
a first inorganic insulating layer disposed on a side of the first organic insulating layer facing away from the base substrate, wherein the first inorganic insulating layer is provided with a plurality of second openings, the second opening corresponds to the conductive pad, and an orthographic projection of the second opening on the base substrate is within an orthographic projection of the corresponding conductive pad on the base substrate.

16. The display device according to claim 15, wherein the display substrate further comprises: a conductive anti-oxidation layer, wherein the conductive anti-oxidation layer is disposed on the base substrate provided with the first inorganic insulating layer, an orthographic projection of the conductive anti-oxidation layer on the base substrate is within an orthographic projection of the second opening on the base substrate, and the conductive anti-oxidation layer covers a surface, away from the base substrate, of a pad region of the conductive pad, the pad region being a region of the conductive pad which is exposed from the second opening.

17. The display device according to claim 15, wherein a minimum distance between two adjacent conductive pads is greater than or equal to a first preset value, and the first opening corresponds to one conductive pad.

18. The display device according to claim 15, wherein a minimum distance between two adjacent conductive pads is less than a first preset value, and the first opening corresponds to a plurality of conductive pads.

19. The display device according to claim 17, wherein the first preset value ranges from 30 μm to 60 μm.

20. The display device according to claim 15, wherein the plurality of conductive pads comprise a plurality of first conductive pads and a plurality of second conductive pads; wherein
every two first conductive pads constitute one first conductive pad group, and one first conductive pad group is configured to be connected to one light-emitting device;
every N second conductive pads constitute one second conductive pad group, and one second conductive pad group is configured to be connected to one driver chip; and
the first openings comprise a first sub-opening and a second sub-opening, wherein the first sub-opening corresponds to one first conductive pad group, and the second sub-opening corresponds to one second conductive pad group.
